(19) United States
(12) Patent Application Publication
(10) Pub. No.: US 2008/0124547 A1
(43) Pub. Date: May 29, 2008

(54) PARTIALLY INSULATION COATED METAL WIRE FOR WIRE BONDING AND WIRE BONDING METHOD FOR SEMICONDUCTOR PACKAGE USING THE SAME

(75) Inventors: Min-Ho O, Daegu (KR); Chan PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/942,575

(22) Filed: Nov. 19, 2007

(30) Foreign Application Priority Data
Nov. 28, 2006 (KR) 2006-0118555

(51) Int. Cl. B32B 15/02; H01L 21/44

(52) U.S. Cl. 428/379; 438/666; 257/E21.476

(57) ABSTRACT

An insulation coated metal wire for wire bonding is provided. The insulation coated metal wire comprises a metal wire; and an insulating layer partially coated on the surface of the metal wire to allow a contact area of the insulating layer with bonding pads to be small. Accordingly, an insulating property is maintained and adhesion of the insulation coated metal wire with the pad is enhanced.

### CROSS-REFERENCE TO RELATED PATENT APPLICATION

This application claims priority under 35 USC § 119 to Korean Patent Application No. 10-2006-0118555, filed on Nov. 28, 2006 in the Korean Intellectual Property Office, the disclosure of which is incorporated herein in its entirety by reference.

### BACKGROUND

1. Technical Field

The present invention relates to an insulation coated metal wire used for wire bonding and a wire bonding method for a semiconductor package using the same. Specifically, the present invention relates to a partially insulation coated metal wire and a wire bonding method for a semiconductor package using the same.

2. Description of the Related Art

In a semiconductor package, an interconnection substrate, e.g., a printed circuit board (PCB) or bonding pad (or a lead) of a lead frame, and a chip pad of a semiconductor chip are bonded using a metal wire so as to be electrically connected to each other. Such a process is referred to as a wire bonding process and the connection between the interconnection substrate and the semiconductor chip using the metal wire may be referred to as a wire bond. As chip pads of semiconductor chips become more miniaturized and stacked packages having multi-layered semiconductor chips stacked therein are manufactured using a wire bonding process, the instances of short circuits, which occur when metal wires contact each other, have increased. Accordingly, an insulation coated metal wire in which a surface of a metal wire is coated with an insulating layer, has been increasingly used.

FIGS. 1 and 2 are perspective and cross-sectional views, respectively, showing a conventional insulation coated metal wire, and FIG. 3 is a schematic view showing a bonding section of the insulation coated metal wire of FIGS. 1 and 2 after the insulation coated metal wire has been bonded to a pad.

Specifically, the insulation coated metal wire 15 includes a metal wire 11 having a circular cross-section, and an insulating layer 13, completely coating a surface of the metal wire 11, also having a circular cross-section. If a wire bonding process is performed with the insulation coated metal wire 15, an insulating property between metal wires is improved in a semiconductor package. However, an insulating material layer 17 exists on a bonding section of the metal wire 11 as shown in FIG. 3. The insulating material layer 17 significantly deteriorates adhesion (or adhesive strength) between pads (chip pads or bonding pads) and the metal wire. This may result in premature failure of the wire bond during subsequent processing steps, such as a molding process, or during operation of the semiconductor package. Consequently, a metal wire for wire bonding and a method of wire bonding that does not result in an insulating material layer between the metal wire and the pads is desired.

### SUMMARY

The present invention provides a partially insulation coated metal wire for wire bonding capable of enhancing adhesion between a pad and the metal wire while maintaining an insulating property between metal wires for wire bonding. The present invention also provides a wire bonding method for a semiconductor package using a partially insulation coated metal wire for wire bonding.

According to an aspect of the present invention, there is provided an insulation coated metal wire for wire bonding, which includes: a metal wire; and an insulating layer partially coated on the surface of the metal wire to allow a contact area of the insulating layer with bonding pads to be small so that an insulating property can be maintained and adhesion of the insulation coated metal wire with the pad can be enhanced.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are perspective and cross-sectional views, respectively, showing a conventional insulation coated metal wire;

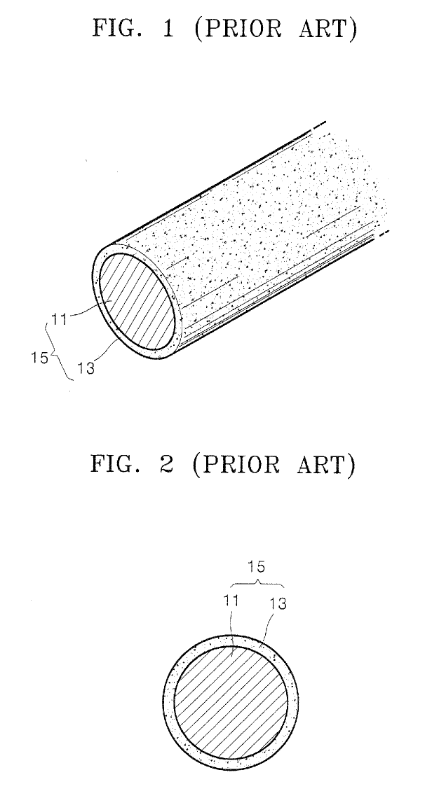

FIG. 3 is a schematic view showing a bonding section of the insulation coated metal wire of FIGS. 1 and 2 after the insulation coated metal wire has been bonded to a pad;

FIG. 4 is a cross-sectional view illustrating a wire bonding process of a conventional insulation coated metal wire;

FIGS. 5 and 6 are perspective and cross-sectional views, respectively, showing a partially insulation coated metal wire according to an embodiment of the present invention;

FIGS. 7 and 8 are perspective and cross-sectional views, respectively, showing a partially insulation coated metal wire according to another embodiment of the present invention;

FIGS. 9 through 12 are cross-sectional views illustrating a wire bonding process for a semiconductor package using a partially insulation coated metal wire according to the present invention;

FIGS. 13 and 14 are enlarged perspective views showing examples of semiconductor packages bonded using partially insulation coated metal wires according to an embodiment of the present invention; and

FIGS. 15 and 16 are cross-sectional views illustrating a wire bonding process of a stacked semiconductor package bonded using partially insulation coated metal wires according to an embodiment of the present invention.

### DETAILED DESCRIPTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

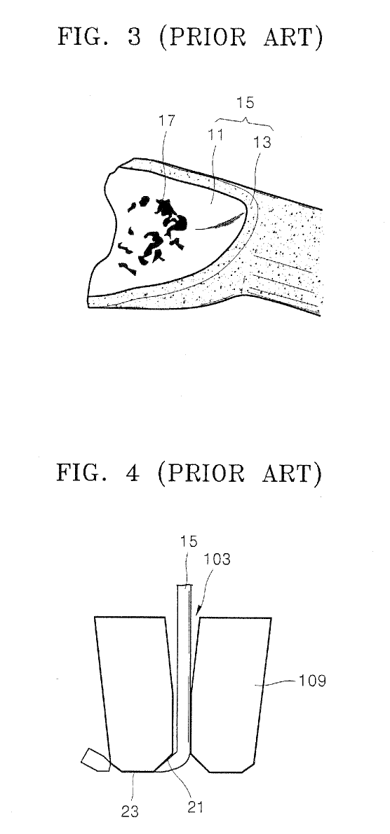

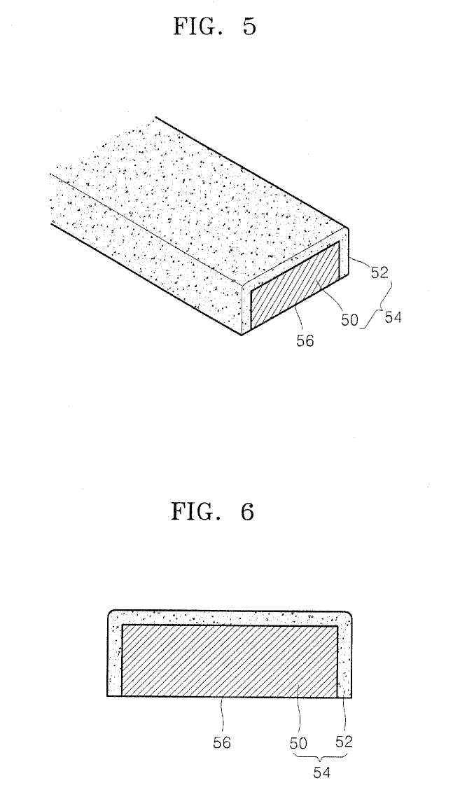

First, the present inventors studied the process in which the insulating material layer 17 is formed on a bonding section of the conventional insulation coated metal wire 15 in a wire bonding process as shown in FIG. 3. This will be described below with reference to FIG. 4.

FIG. 4 is a cross-sectional view illustrating a wire bonding process of a conventional insulation coated metal wire.

Specifically, a bonding tool 109 having a capillary is used in a wire bonding process as shown in FIG. 4. A bonding wedge may be used as the bonding tool 109. A through-hole 103 is formed in the bonding tool 109, and an insulation coated metal wire 15 is inserted into the through-hole 103 to pass therethrough. The insulation coated metal wire 15 inserted into the through-hole 103 is bonded on a pad (not shown) through a compression method, e.g., a thermo-compression method. The bonding is completed by cutting the insulation coated metal wire 15 while moving the bonding tool 109 up after the insulation coated metal wire 15 is bonded to the pad. Such a bonding method is referred to as wedge bonding or stitch bonding.

However, the present inventors found that, since the bonding is performed while the metal wire 15 is cut by an outer edge of a chamfer portion 21 of the bonding tool 109 in the bonding process, the insulating material layer 17 remains between the metal wire 15 and a pad, i.e., on a bonding section of the metal wire 15, as shown in FIG. 3. Thus, the adhesive strength between the pad and the metal wire 15 is reduced.

Accordingly, the present inventors found that, when an insulating layer is partially coated such that the contact area between pads, e.g., chip and bonding pads, and the insulating layer of a metal wire is small, an insulating property between metal wires can be maintained and adhesion with a pad can be enhanced in wire bonding. It will be apparent that a metal wire partially insulation coated (hereinafter, referred to as a “partially insulation coated metal wire”) effectively prevents an insulating material layer from being produced on a bonding section even during ball bonding, to be described later, so that an insulating property can be maintained and adhesion with a pad can be enhanced. This will be described in detail with reference to the following embodiments.

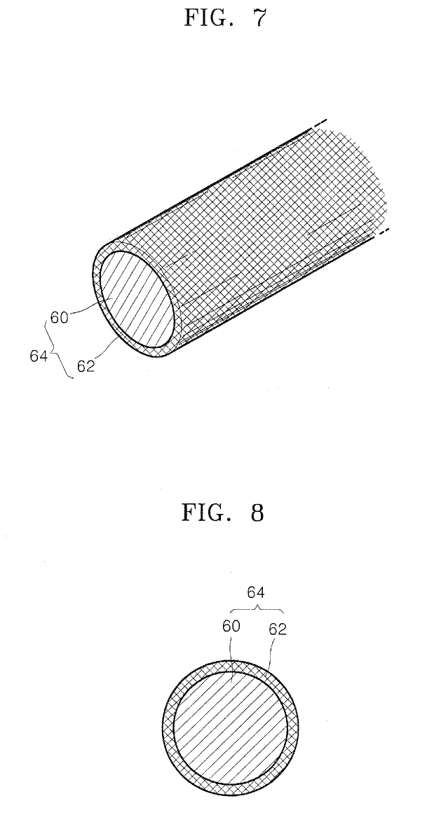

FIGS. 5 and 6 are perspective and cross-sectional views, respectively, showing a partially insulation coated metal wire according to an embodiment of the present invention.

Specifically, the partially insulation coated metal wire 54 according to an embodiment of the present invention includes a metal wire 50 with a flat-plate-shaped cross-section, and an insulating layer 52 in which a portion 56 of the metal wire 50, to be bonded to a pad in a wire bonding process on a surface thereof, e.g., a bottom section, is not coated with the insulating layer 52. As shown in FIG. 6, a portion of a lateral surface of the metal wire 50 is exposed by the insulating layer 52, where a lateral surface is a surface that extends along the length of the metal wire 50. In the example shown in FIGS. 5 and 6, the exposed lateral surface of the metal wire 50 is the bottom surface 56. A ribbon-shaped or tape-shaped metal wire may be used as the metal wire 50 with a flat-plate-shaped cross-section. The metal wire 50 may be made of Al, Cu, Au, Ag or Ni. The insulating layer 52 may be made of silicon, polyimide resin, epoxy resin or urethane resin.

Consequently, since a portion of the partially insulation coated metal wire 54 according to this embodiment of the present invention, which is to be bonded with a pad, is not coated with the insulating layer 52 such that a contact area of the insulating layer 52 with the pad is small in a wire bonding process, an insulating property between the metal wires 50 can be maintained and adhesion (or adhesive strength) with the pad can be enhanced. Thereby, subsequent failures of the wire bonds due to either shorts between wires or opens between the wires and the pads can be prevented.

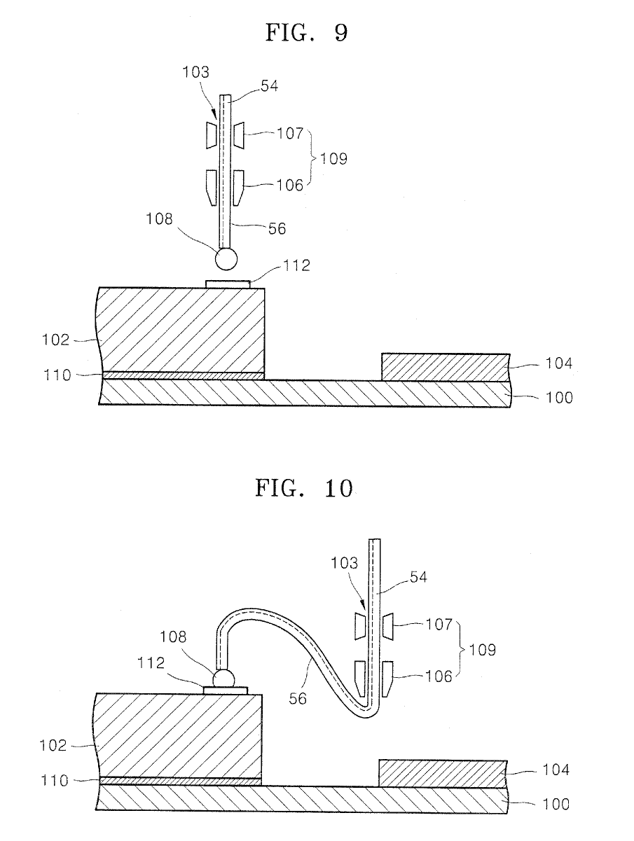

FIGS. 7 and 8 are perspective and cross-sectional views, respectively, showing a partially insulation coated metal wire according to another embodiment of the present invention.

Specifically, the partially insulation coated metal wire 64 according to this embodiment of the present invention includes a metal wire 60 with a circular cross-section, and an insulating layer 62 coated in a net shape (or a lattice shape) on a surface of the metal wire 60. The metal wire 60 may be made of Al, Cu, Au, Ag or Ni.

The insulating layer 62 may be composed of silicon, polyimide resin, epoxy resin or urethane resin. As the insulating layer 62 is formed in a net shape, the surface of the metal wire 60 is not all coated but is partially coated. In other words, a portion of the lateral surface of the metal wire 60 is exposed due to the insulating layer 62 being formed in a net shape. Accordingly, in the partially insulation coated metal wire 64 according to this embodiment of the present invention, an insulating property between the metal wires 60 can be maintained in a wire bonding process, and a contact area between the insulating layer 62 and a pad is small so that adhesion with the pad can be enhanced.

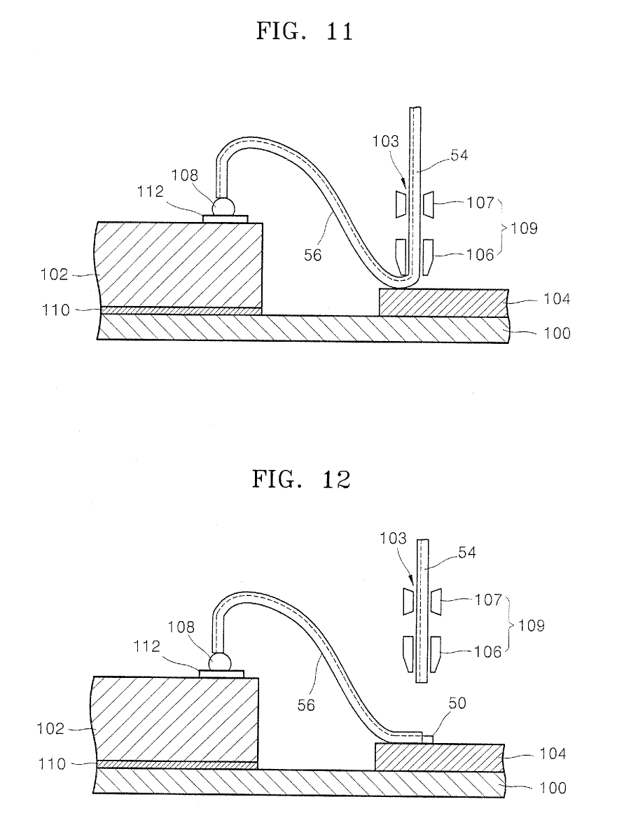

Hereinafter, an exemplary wire bonding process between a chip pad of a semiconductor chip and a bonding pad of an interconnection substrate using the partially insulation coated metal wire 54 of FIGS. 5 and 6 will be described with reference to FIGS. 9 through 12. It will be apparent that the same wire bonding process can be performed with reference to the partially insulation coated metal wire 64 of FIGS. 7 and 8. Furthermore, although a capillary is used as a bonding tool in a wire bonding process, a bonding wedge may also be used as the bonding tool.

FIGS. 9 through 12 are cross-sectional views illustrating a wire bonding process for a semiconductor package using a partially insulation coated metal wire according to an embodiment of the present invention.

Referring to FIG. 9, a semiconductor chip 102 is attached on an interconnection substrate 100, e.g., a PCB or lead frame, using an adhesive layer 110, and a bonding pad 104 is formed spaced apart from the semiconductor chip 102. In a case where the interconnection substrate 100 is a lead frame, the bonding pad 104 may be referred to as a lead. A chip pad 112 is positioned on the semiconductor chip 102, and a bonding tool 109 is positioned above the chip pad 112.

The bonding tool 109 includes a guide 107 and a capillary 106. A through-hole 103 is formed in the bonding tool 109, i.e., the guide 107 and the capillary 106, as described above. After allowing the partially insulation coated metal wire 54 to pass through the through-hole 103, a ball portion 108 is formed at a front end of the partially insulation coated metal wire 54. The ball portion 108 may be formed using an electric discharge. For example, an electrode (not shown) may be placed close to the front end of the partially insulation coated metal wire 54 introducing an electric discharge through the front end of the partially insulation coated metal wire 54, which causes the front end to partially melt and form into a ball shape.

Referring to FIG. 10, the partially insulation coated metal wire 54 passing through the through-hole 103 is bonded on the chip pad 112 of the semiconductor chip 102 through a compression method, e.g., a thermo-compression method. The compression method may comprise one or more of heat, pressure, and ultrasonic vibration. Such a method of bonding after forming the ball portion 108 is referred to as ball bonding. Since a lower section 56 of the partially insulation coated metal wire 54 is exposed in the ball bonding process, a contact area of the insulating layer 52 with the chip pad 112 is small, thereby reducing the amount of an insulating material layer formed on a bonding section of the metal wire 54.

Accordingly, the present invention can maintain an insulating property between the partially insulation coated metal wires 54 on the semiconductor chip 102 and enhance adhesion between the partially insulation coated metal wires 54 and corresponding chip pads 112. Subsequently, the metal wire 54 forms a predetermined loop while the bonding tool 109 is moved toward the bonding pad 104.

Referring to FIGS. 11 and 12, after moving the bonding tool 109 above the bonding pad 104, the partially insulation coated metal wire 54 is compressed on the bonding pad 104. Subsequently, as shown in FIG. 12, the partially insulation coated metal wire 54 on the bonding pad 104 is cut while the bonding tool 109 is moved vertically away from the bonding pad 104 after the partially insulation coated metal wire 54 is compressed. Thus, bonding is completed. Accordingly, the chip pad 112 and the bonding pad 104 are connected electrically to each other. Furthermore, a bonding method in which a metal wire is cut in a compression state without forming a ball portion is referred to as wedge bonding or stitch bonding and the partially insulation coated metal wire 54 may be utilized in a wedge/stitch bonding method as well.

Since a lower section 56 of the partially insulation coated metal wire 54 is exposed in wedge or stitch bonding, a contact area of the insulating layer 52 with the bonding pad 104 is small. Thus, the amount of an insulating material layer formed on a bonding section of the metal wire 54 can be reduced. Accordingly, the present invention can maintain an insulating property between the partially insulation coated metal wires 54 on the semiconductor chip 102 and enhance adhesion with the bonding pad 104.

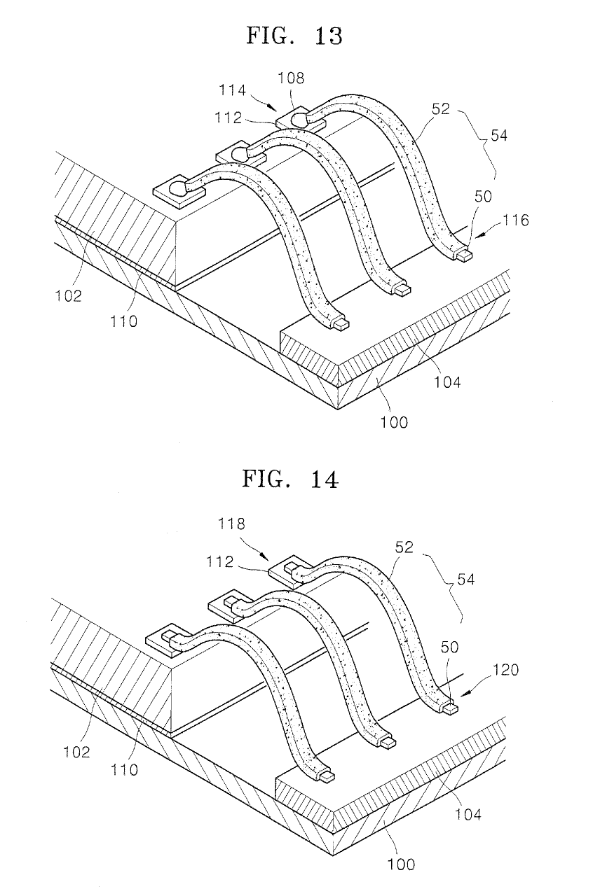

FIGS. 13 and 14 are enlarged perspective views showing examples of semiconductor packages bonded using partially insulation coated metal wires according to an embodiment of the present invention. Like numbers in FIGS. 9 through 12 refer to like elements in FIGS. 13 and 14.

Specifically, FIG. 13 illustrates that ball bonding 114 may be performed using the ball portion 108 on the chip pad 112 of the semiconductor chip 102 bonded by the adhesive layer 110 on the interconnection substrate 100, and wedge or stitch bonding 116 may be performed on the bonding pad 104 of the interconnection substrate 100. The chip and bonding pads 112 and 104 are bonded using the partially insulation coated metal wires 54. As described above, a bottom section of the partially insulation coated metal wire 54 is not coated with an insulating layer.

Furthermore, FIG. 14 illustrates that wedge or stitch bonding 118 may be performed on the chip pad 112 of the semiconductor chip 102 bonded by the adhesive layer 110 on the interconnection substrate 100, and wedge or stitch bonding 120 may also be performed on the bonding pad 104 of the interconnection substrate 100. As in FIG. 13, the chip and bonding pads 112 and 104 are bonded using the partially insulation coated metal wires 54. Particularly, a bottom section of the partially insulation coated metal wire 54 is not coated with an insulating layer. Thus, the partially insulation coated metal wire of the present invention may be used regardless of bonding method.

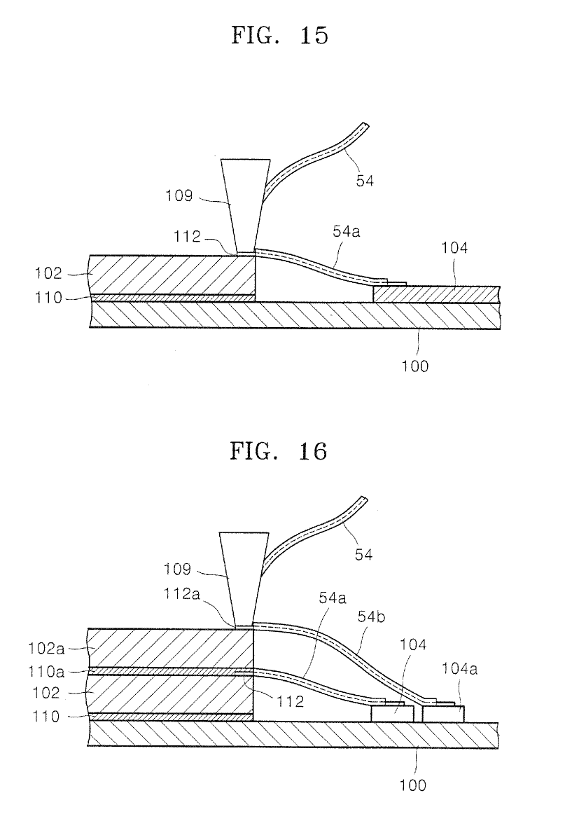

FIGS. 15 and 16 are cross-sectional views illustrating a wire bonding process of a stacked semiconductor package bonded using partially insulation coated metal wires according to an embodiment of the present invention.

Referring to FIG. 15, a first semiconductor chip 102 is attached using a first adhesive layer 110 on an interconnection substrate 100, e.g., a PCB or lead frame. A first bonding pad 104 is formed spaced apart from the first semiconductor chip 102. In a case where the interconnection substrate 100 is a lead frame, the first bonding pad 104 may be referred to as a lead. A first chip pad 112 is positioned on the first semiconductor chip 102.

A first partially insulation coated metal wire 54a is bonded on the first chip pad 112 of the first semiconductor chip 102 and the first bonding pad 104 using a bonding tool 109 through a compression method as described above. The bonding may be performed by any of a ball, wedge or stitch bonding method. The first partially insulation coated metal wire 54a allows a contact area of the insulating layer with the pads 112 and 104 to be small, thereby reducing the amount of an insulating material layer formed on a bonding section. Accordingly, in the first partially insulation coated metal wire 54a on the first semiconductor chip 102 and the first bonding pad 104, an insulating property can be maintained, and adhesion with pads, i.e., the first chip pad 112 and the first bonding pad 104, can be enhanced. Particularly, a portion which is not coated with an insulating layer is configured to face downward during wire bonding, thus, an insulating property between partially insulation coated metal wires 54a and 54b can be more enhanced once the second semiconductor chip 102a is wire bonded in the following process.

Referring to FIG. 16, a second semiconductor chip 102a is attached on the first semiconductor chip 102 using a second adhesive layer 110a. Subsequently, the second partially insulation coated metal wire 54b, through a compression method as described above, is bonded on a second chip pad 112a of the second semiconductor chip 102a and a second bonding pad 104a using the bonding tool 109 as described above with reference to FIG. 12. The bonding method and advantages of the bonding method are as described above with reference to FIG. 12.

Furthermore, in the present invention, a portion which is not coated with an insulating layer is configured to face downward in wire bonding, so that an insulating property between the partially insulation coated metal wires 54a and 54b can be enhanced. It will be apparent that, although the partially insulation coated metal wires 54a and 54b may be influenced by a sealant, e.g., epoxy resin or the like, in a molding process after wire bonding, an insulating property can be enhanced.

As described above, according to embodiments of the present invention, a partially insulation coated metal wire includes an insulating layer partially coated to allow a contact area of the insulating layer with a bonding pad to be small, so that an insulating property can be maintained and adhesion of the partially insulation coated metal wire with a pad can be enhanced.

The partially insulation coated metal wire according to an embodiment of the present invention is a metal wire with a flat-plate-shaped cross-section, and a portion bonded to a pad in a surface of the metal wire is not coated. Furthermore, the partially insulation coated metal wire according to another embodiment of the present invention is a metal wire with a circular cross-section, and an insulating layer is coated on the metal wire in a net shape.

In addition, the present invention provides a wire bonding method for a semiconductor package using a partially insulation coated metal wire. Particularly, the partially insulation coated metal wire includes an insulating layer partially coated to allow a contact area of the insulating layer with pads bonded in wire bonding to be small, so that an insulating property can be maintained and adhesion of the partially insulation coated wire with the pads can be enhanced.

According to an aspect of the present invention, there is provided an insulation coated metal wire for wire bonding, which includes: a metal wire; and an insulating layer partially coated on the surface of the metal wire to allow a contact area of the insulating layer with bonding pads to be small so that an insulating property can be maintained and adhesion of the insulation coated metal wire with the pad can be enhanced, wherein a portion of a lateral surface of the metal wire is exposed by the insulating layer.

The metal wire may be a metal wire having a flat-plate-shaped cross-section, and the surface of a portion of the metal wire to be bonded to a pad may not be coated with the insulating layer. The surface of a bottom section of the metal wire to be bonded to the pad may not be coated. The metal wire having a flat-plate-shaped cross-section may be a ribbon-shaped or tape-shaped metal wire. The metal wire may be a metal wire having a circular cross-section, and the insulating layer may be coated in a net shape.

According to another aspect of the present invention, there is provided an insulation coated metal wire for wire bonding, which includes: a metal wire having a flat-plate-shaped cross-section; and an insulating layer partially coated on the surface of the metal wire to allow the surface of a portion of the metal wire, which is to be bonded to pads, not to be coated so that an insulating property can be maintained and adhesion of the insulation coated metal wire with the pad can be enhanced.

The surface of a bottom section of the metal wire to be bonded to the pads may not be coated. The metal wire having a flat-plate-shaped cross-section may be a ribbon-shaped or tape-shaped metal wire.

According to a further aspect of the present invention, there is provided an insulation coated metal wire for wire bonding, comprising: a metal wire having a circular cross-section; and an insulating layer coated in a net shape on a surface of the metal wire so that an insulating property can be maintained and adhesion of the insulation coated metal wire with the pad can be enhanced.

According to a still further aspect of the present invention, there is provided a wire bonding method for a semiconductor package, which includes: bonding a partially insulation coated metal wire included in a bonding tool on a chip pad of a semiconductor chip; moving the bonding tool after bonding the partially insulation coated metal wire on the chip pad and then bonding the partially insulation coated metal wire on a bonding pad of an interconnection substrate such that the chip pad and the bonding pad are connected electrically to each other; and moving the bonding tool after bonding the partially insulation coated metal wire on the bonding pad and then cutting the partially insulation coated metal wire included in the bonding tool while the bonding tool is spaced apart from the bonding pad, wherein the partially insulation coated metal wire comprises a metal wire and an insulating layer partially coated on the surface of the metal wire to allow a contact area of the insulating layer with bonding pads to be small so an insulating property can be maintained and adhesion of the insulation coated metal wire with the pad can be enhanced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An insulation coated metal wire for wire bonding, comprising:
a metal wire; and
an insulating layer partially coated on the surface of the metal wire, wherein a portion of a lateral surface of the metal wire is exposed by the insulating layer.

2. The insulation coated metal wire of claim 1, wherein the metal wire is a metal wire with a flat-plate-shaped cross-section, and the exposed portion of the lateral surface is a portion of the metal wire to be bonded to a pad and is not coated with the insulating layer.

3. The insulation coated metal wire of claim 2, wherein the surface of a bottom section of the metal wire to be bonded to the pad is not coated with the insulating layer.

4. The insulation coated metal wire of claim 2, wherein the metal wire having a flat-plate-shaped cross-section is a ribbon-shaped or tape-shaped metal wire.

5. The insulation coated metal wire of claim 1, wherein the metal wire is a metal wire having a substantially circular cross-section, and the insulating layer is coated in a net shape.

6. An insulation coated metal wire for wire bonding, comprising:
a metal wire having a flat-plate-shaped cross-section; and
an insulating layer partially coated on the surface of the metal wire such that the surface of a portion of the metal wire is not coated.

7. The insulation coated metal wire of claim 6, wherein the surface of a bottom section of the metal wire to be bonded to pads is not coated.

8. The insulation coated metal wire of claim 6, wherein the metal wire having a flat-plate-shaped cross-section is a ribbon-shaped or tape-shaped metal wire.

9. An insulation coated metal wire for bonding, comprising:
a metal wire having a substantially circular cross-section; and
an insulating layer coated in a net shape on a surface of the metal wire.

10. A wire bonding method for a semiconductor package, comprising:
bonding a partially insulation coated metal wire on a chip pad of a semiconductor chip using a bonding tool;
moving the bonding tool and bonding the partially insulation coated metal wire on a bonding pad of an interconnection substrate such that the chip pad and the bonding pad are connected electrically to each other; and
moving the bonding tool and cutting the partially insulation coated metal wire while the bonding tool is spaced apart from the bonding pad,
wherein the partially insulation coated metal wire comprises a metal wire and an insulating layer partially coated on the surface of the metal wire, the insulating layer exposing a portion of a surface of the metal wire.

11. The wire bonding method for a semiconductor package of claim 10, wherein the metal wire is a metal wire having a flat-plate-shaped cross-section, and the surface of the portion of the metal wire to be bonded to the bonding and chip pads is not coated with the insulating layer.

12. The wire bonding method for a semiconductor package of claim 11, wherein the surface of a bottom section of the metal wire is not coated with the insulating layer.

13. The wire bonding method for a semiconductor package of claim 11, wherein the metal wire having a flat-plate-shaped cross-section is a ribbon-shaped or tape-shaped metal wire.

14. The wire bonding method for a semiconductor package of claim 10, wherein the metal wire is a metal wire having a substantially circular cross-section and the insulating layer is coated in a net shape.

15. The wire bonding method for a semiconductor package of claim 10, wherein the partially insulation coated metal wire and the chip pad of the semiconductor chip are bonded using a ball or wedge bonding method.

16. The wire bonding method for a semiconductor package of claim 10, wherein the partially insulation coated metal wire and the bonding pad of the interconnection substrate are bonded using a wedge bonding method.
